(19) United States
(12) Patent Application Publication
(10) Pub. No.: US 2026/0239662 A1
(43) Pub. Date: Aug. 13, 2026

(54) SEMICONDUCTOR DEVICE

(71) Applicant: Minebea Power Semiconductor Device Inc., Ibaraki (JP)

(72) Inventor: Kenji HARA, Hitachi-shi (JP)

(21) Appl. No.: 19/471,442

(22) PCT Filed: Feb. 1, 2024
(86) PCT No.: PCT/JP2024/003282

§ 371 Date: Oct. 1, 2025

(30) Foreign Application Priority Data
Apr. 27, 2023 (JP) 2023-073392

(51) Int. Cl. H10D 30/65; H10D 62/10; H10W 10/10

(52) U.S. Cl. CPC H10D 30/657; H10D 62/102; H10D 62/126; H10W 10/181

(57) ABSTRACT

A semiconductor device capable of suppressing a saturation current in a MOSFET includes a drift region of a first conductivity type, a body region of a second conductivity type, a channel region formed in the body region, a source region of the first conductivity type, a drain region of the first conductivity type provided on the same main surface side as the source region, a gate electrode, and a gate insulating film provided between the gate electrode and the channel region. A separation region in which an insulating film is provided inside a trench is provided between the drain region and the body region. The drift region has a first extension portion having a longitudinal direction in a first direction and is sandwiched by the body region when viewed in plan view, and constitutes a part of a current path between the channel region and the drain region.

### TECHNICAL FIELD

This invention relates to a semiconductor device.

### BACKGROUND ART

As one type of semiconductor device, there is a MOSFET (Metal Oxide Semiconductor Field Effect Transistor). The MOSFET is used for a variety of purposes. However, for example, in a gate drive circuit which drives a high breakdown voltage output element, etc., there is a case where it is desirable to avoid much increasing a current flow even when the MOSFET is on at a high breakdown voltage, i.e., a characteristic in which a saturation current is suppressed is required.

As the MOSFETs each capable of suppressing the saturation current, there are structures as illustrated in the following FIGS. 11 to 14, for example.

FIG. 11 is a top view illustrating an example of a conventional semiconductor device. FIG. 12 is a cross-sectional view taken along line A-A in FIG. 11.

The conventional semiconductor device 1 illustrated in FIG. 11 is a horizontal MOSFET and has a long channel region 9 between a drain region 6 and a source region 4. By extending the channel region 9 as illustrated in FIG. 11, the resistance (channel resistance) in the channel region 9 becomes high and hence the saturation current can be suppressed. Incidentally, when the channel region 9 is made long, a characteristic is obtained in which a linear region of a current ends at a relatively low drain voltage.

FIG. 13 is a top view illustrating another example of a conventional semiconductor device. FIG. 14 is a cross-sectional view taken along line A-A in FIG. 13.

The conventional semiconductor device 1 illustrated in FIG. 13 is a horizontal MOSFET and has a long drift region 2 between a drain region 6 and a source region 4. By extending the drift region 2 as illustrated in FIG. 13, the resistance (drift resistance) in the drift region 2 becomes high and hence the saturation current can be suppressed. Incidentally, when the drift region 2 is made long, a characteristic is obtained in which a linear region of a current continues to a relatively high drain voltage.

Further, as a type having a long drift region, there is one shown in Patent Literature 1, for example. In FIG. 3A and FIG. 3B and the paragraphs 0045 to 0049 of Patent Literature 1, a horizontal high breakdown voltage NMOS transistor has been described in which an N-type drift region (62) and a field plate member (64) are alternately formed. Incidentally, an oxide layer (69) is formed between the N-type drift region (62) and the field plate member (64). Further, the field plate member (64) is connected to the ground, and the source is connected to the field plate member (64) or is in a floating state. According to Patent Literature 1, it is described that a high voltage transistor which maintains a high voltage in an OFF state can be provided.

### CITATION LIST

### Patent Literature

PTL 1: Japanese Unexamined Patent Application Publication No. 2011-151408

### SUMMARY OF INVENTION

### Technical Problem

However, in the horizontal MOSFET, in order to suppress the saturation current, when the long channel region 9 is provided as illustrated in FIG. 11 or the long drift region 2 is provided as illustrated in FIG. 13, there is a need to increase the distance between the drain region 6 and the source region 4 in order to obtain a high resistance component, and there is a problem that an element size becomes large.

In the paragraph 0035 of Patent Literature 1, it is described that when the voltage between the drain and the source becomes high in the OFF state, the drift region is depleted due to the field plate existing on both sides of the drift region. Therefore, although not explicitly described in Patent Literature 1, it is presumed that when the voltage between the drain and the source becomes high similarly even in the ON state, the drift region is depleted due to the field plate existing on both sides of the drift region. It is presumed that when the drift region is depleted, the resistance becomes high and the saturation current can be suppressed.

However, Patent Literature 1 is accompanied by problems that there is a need to form a field plate, and a manufacturing process becomes complicated.

An object of the present invention is to provide a semiconductor device capable of suppressing a saturation current with a high breakdown voltage and a small element size by a simple structure in a horizontal MOSFET.

### Solution to Problem

In order to solve the above-described problems, there is provided a semiconductor device of the present invention which includes a drift region of a first conductivity type, a body region of a second conductivity type, a channel region formed in the body region, a source region of the first conductivity type, a drain region of the first conductivity type provided on the same main surface side as the source region, a gate electrode, and a gate insulating film provided between the gate electrode and the channel region. In the semiconductor device, a separation region in which an insulating film is provided inside a trench is provided between the drain region and the body region, and the drift region has a first extension portion which has a longitudinal direction in a first direction by being sandwiched by the body region when viewed in a plan view, and which constitutes a part of a current path between the channel region and the drain region.

### Advantageous Effects of Invention

According to the present invention, in a horizontal MOSFET, it is possible to suppress a saturation current with a high breakdown voltage and a small element size by a simple structure.

### BRIEF DESCRIPTION OF DRAWINGS

FIG. 1 is a top view of a semiconductor device according to a first embodiment.

FIG. 2 is a cross-sectional view taken along line A-A in FIG. 1.

FIG. 3 is a cross-sectional view taken along line B-B in FIG. 1.

FIG. 4 is a cross-sectional view taken along line C-C in FIG. 1.

FIG. 5 is a top view of a semiconductor device according to a second embodiment.

FIG. 6 is a cross-sectional view taken along line C-C in FIG. 5.

FIG. 7 is a top view of a semiconductor device according to a third embodiment.

FIG. 8 is a cross-sectional view taken along line A-A in FIG. 7.

FIG. 9 is a cross-sectional view taken along line B-B in FIG. 7.

FIG. 10 is a top view of a semiconductor device according to a fourth embodiment.

FIG. 11 is a top view illustrating an example of a conventional semiconductor device.

FIG. 12 is a cross-sectional view taken along line A-A in FIG. 11.

FIG. 13 is a top view illustrating another example of a conventional semiconductor device.

FIG. 14 is a cross-sectional view taken along line A-A in FIG. 13.

### DESCRIPTION OF EMBODIMENTS

Hereinafter, embodiments of the present invention will be described with reference to the drawings. In each of the drawings and each embodiment, the same or similar components are denoted by the same reference numerals, and dual description thereof will be omitted.

### First Embodiment

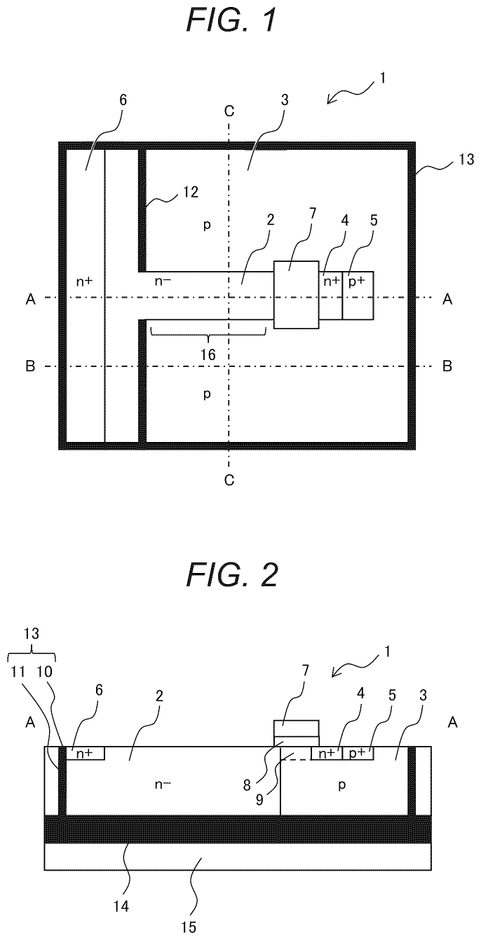

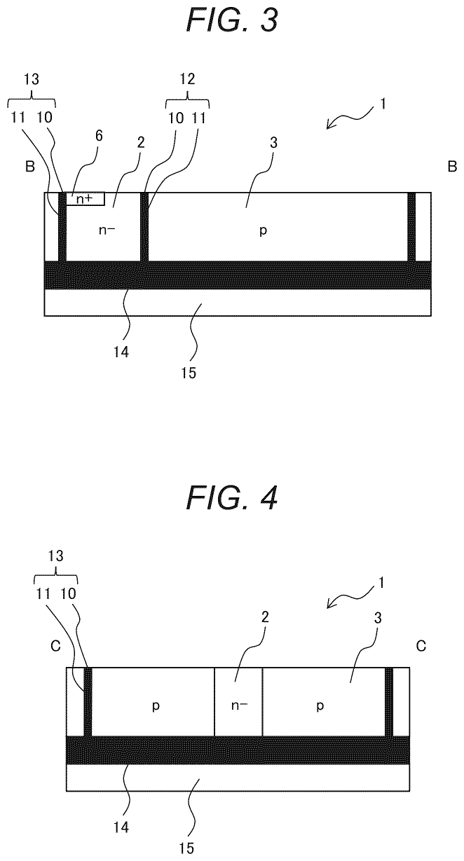

FIG. 1 is a top view of a semiconductor device according to a first embodiment. FIG. 2 is a cross-sectional view taken along line A-A in FIG. 1. FIG. 3 is a cross-sectional view taken along line B-B in FIG. 1. FIG. 4 is a cross-sectional view taken along line C-C in FIG. 1.

The semiconductor device 1 of the first embodiment is a horizontal MOSFET, and includes a drift region 2 of a first conductivity type, a body region 3 of a second conductivity type, a channel region 9 formed in the body region 3, a source region 4 of the first conductivity type, a drain region 6 of the first conductivity type provided on the same main surface side as the source region 4, a gate electrode 7, and a gate insulating film 8 provided between the gate electrode 7 and the channel region 9. The gate electrode 7 can be formed of, for example, polysilicon or the like. The gate insulating film 8 can be formed of, for example, SiO2 or the like. The drift region 2, the body region 3, the channel region 9, the source region 4, the drain region 6, and a contact region 5 to be described later can be formed of, for example, a semiconductor such as silicon or silicon carbide.

The semiconductor device 1 of the present embodiment has a support substrate 15 such as a silicon substrate, and an embedded insulating film 14 formed on the support substrate 15, for example. An SOI (Silicon on Insulator) structure in which the above-described horizontal MOSFET is formed on the embedded insulating film 14 such as SiO2, for example is described as an example, but the present invention is not limited thereto.

Further, the semiconductor device 1 of the present embodiment includes an element isolation region 13 which surrounds a switching element formed by the drift region 2, the body region 3, the channel region 9, the source region 4, the drain region 6, the gate electrode 7, and the gate insulating film 8, and in which an insulating film 10 is provided inside a trench 11. The insulating film 10 can be formed of, for example, SiO2 or the like.

In addition, the semiconductor device 1 includes an unillustrated source electrode and an unillustrated drain electrode. The source electrode is formed of, for example, a metal such as aluminum, is connected to the source region 4, and is connected to the body region 3 via the contact region 5 of the second conductivity type. The drain electrode is formed of, for example, a metal such as aluminum, and is connected to the drain region 6.

Note that in the present embodiment, the n-type MOSFET in which the first conductivity type is an n-type and the second conductivity type is a p-type has been described as the example, but the present invention is not limited thereto, and the first conductivity type may be a p-type and the second conductivity type may be an n-type.

There is shown an example in which as for the impurity concentration, the source region 4 and the drain region 6 have a high concentration of n+ type, the drift region 2 has a low concentration of n− type, the contact region 5 has a high concentration of p+ type, and the body region 3 has a p− type, but the present invention is not limited thereto. It is possible to appropriately change them within a range in which an operation intended in the present embodiment is possible.

Here, in the semiconductor device 1 of the present embodiment, when the drift region 2 is viewed in a plan view, the drift region 2 has a first extension portion 16 which has a longitudinal direction in a first direction by being sandwiched by the body region 3 and which constitutes a part of a current path between the channel region 9 and the drain region 6. That is, since the drift region 2 has a long drift region 2 such as in the first extension portion 16, and further, the body region 3 has a shape surrounding three sides of the first extension portion 16, so that both sides of the first extension portion 16 are shaped so as to be sandwiched by the body region 3.

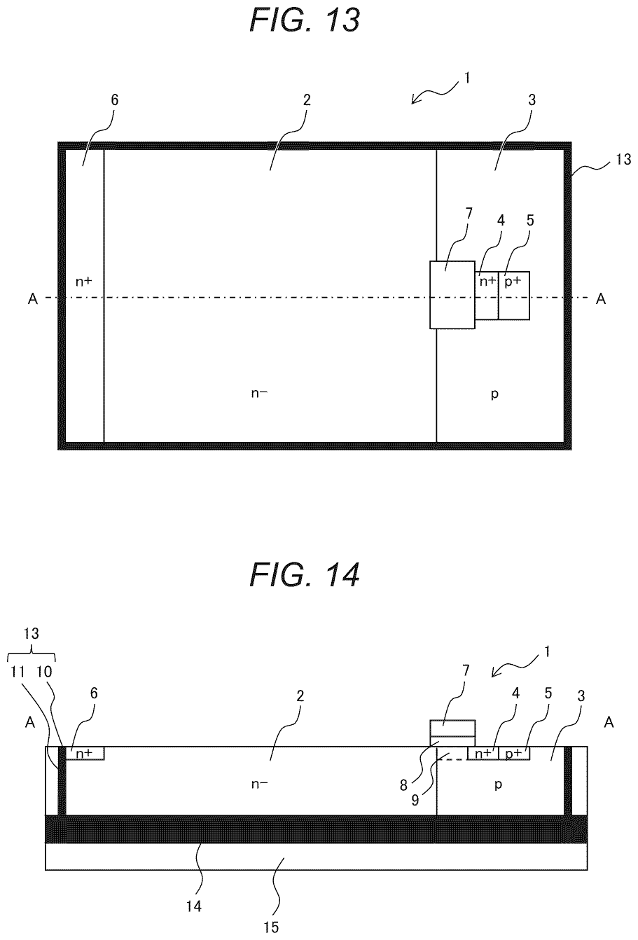

In the semiconductor device 1 of the present embodiment, since the drift region 2 has the long drift region 2 such as in the first extension portion 16, the drift resistance increases, and hence a saturation current can be suppressed. Further, since the first extension portion 16 is sandwiched by the body region 3, when a drain potential becomes high and a potential difference with a source potential becomes large, an electric field is applied to the first extension portion 16 so that the depletion of the first extension portion 16 proceeds, and the first extension portion 16 becomes high in resistance. Therefore, the saturation current is suppressed even by the effect of high resistance by the electric field. Therefore, the length of the first extension portion 16 can be made shorter than in the example of FIG. 13 in the related art. Therefore, the element size can be reduced.

Here, as the shape of the body region 3 is formed so as to sandwich the first extension portion 16, the distance between the body region 3 to be the source potential and the drain region 6 to be the drain potential becomes close, and the breakdown voltage may decrease.

Therefore, the semiconductor device 1 of the present embodiment is configured such that a separation region 12 is provided between the drain region 6 and the body region 3, and in the separation region 12, the insulating film 10 is provided inside the trench 11. Thus, the insulation is secured between the region to be the source potential and the region to be the drain potential, and the breakdown voltage can be ensured with a small element size.

Note that since the separation region 12 and the element isolation region 13 can be formed together in the same manufacturing process, the pattern may only be changed. Note that by adopting a structure in which the element isolation region 13 and the separation region 12 are connected, it is possible to facilitate manufacture and to reliably perform insulation.

Further, since the shape of the drift region 2 and the body region 3 can also be realized only by changing the pattern, the structure is simple, and the manufacturing process does not increase.

Incidentally, although there is shown the example in which the drain region 6 of the present embodiment is provided on the extension line of the first extension portion 16, the present invention is not limited thereto. As in third and fourth embodiments to be described later, the drain region 6 can also be applied to a case where it is not provided on the extension line of the first extension portion 16.

As described above, according to the semiconductor device 1 of the present embodiment, in the horizontal MOSFET, the saturation current can be suppressed with a high breakdown voltage and a small element size by a simple structure. Further, since the shape can be realized only by changing the pattern, the manufacturing process does not increase.

### Second Embodiment

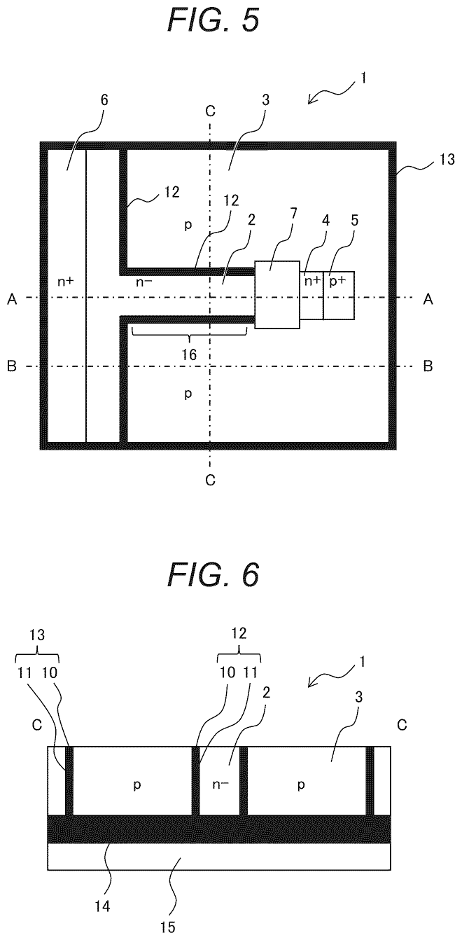

FIG. 5 is a top view of a semiconductor device according to a second embodiment. FIG. 6 is a cross-sectional view taken along line C-C in FIG. 5.

The second embodiment is a modification of the first embodiment. The semiconductor device 1 of the second embodiment is different from the first embodiment in that the separation region 12 is also provided between the body region 3 and the first extension portion 16. Thus, it is possible to reliably perform insulation. Those other than these are the same as in the first embodiment. A cross-sectional view taken along line A-A in FIG. 5 is the same as that in FIG. 2, and a cross-sectional view taken along line B-B in FIG. 5 is the same as that in FIG. 3.

### Third Embodiment

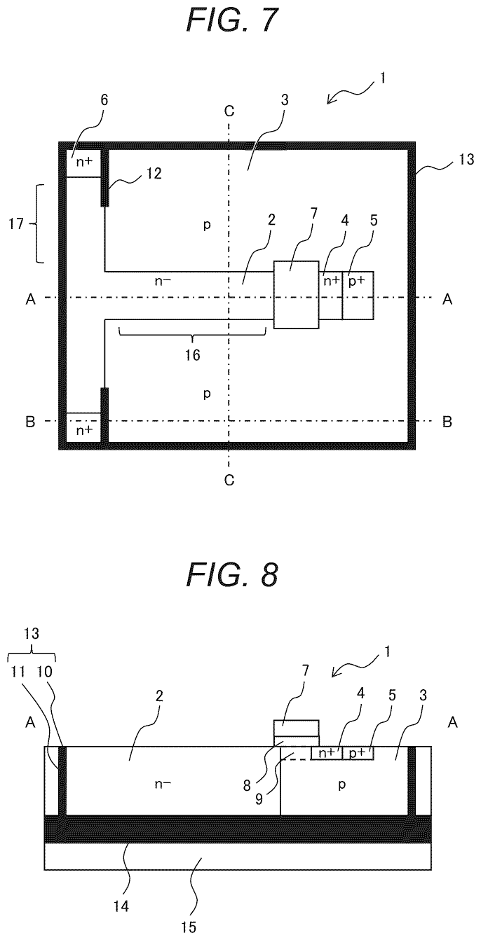

FIG. 7 is a top view of a semiconductor device according to a third embodiment. FIG. 8 is a cross-sectional view taken along line A-A in FIG. 7.

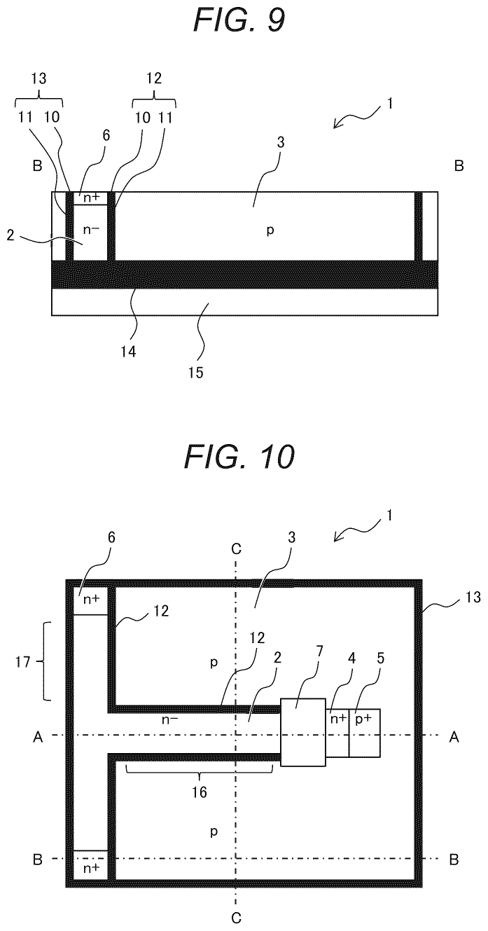

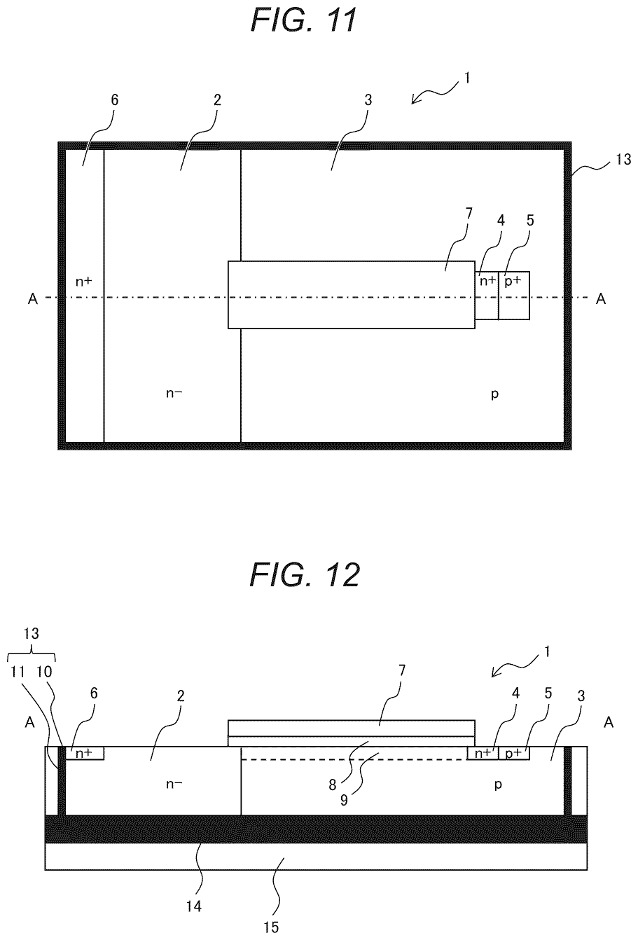

FIG. 9 is a cross-sectional view taken along line B-B in FIG. 7.

The third embodiment is a modification of the first embodiment. The semiconductor device 1 of the third embodiment is different from the first embodiment in that the drift region 2 has a second extension portion 17 having a longitudinal direction in a second direction different from the first direction and constituting a part of a current path between the channel region 9 and the drain region 6 when viewed in a plan view, and the drain region 6 is provided on an extension line of the second extension portion 17. Those other than this are the same as in the first embodiment, and a cross-sectional view taken along line C-C in FIG. 7 is the same as that in FIG. 4.

According to the present embodiment, since the drift region 2 has a long drift region 2 such as in the second extension portion 17 in addition to the first extension portion 16, the drift resistance further increases, and hence the saturation current can be further suppressed. Note that the element size can be further reduced while suppressing the saturation current if the increase in the drift resistance due to the second extension portion 17 is utilized not to suppress the saturation current but to shorten the first extension portion 16.

In the present embodiment, the separation region 12 is also provided between the body region 3 and the second extension portion 17. Thus, the insulation is secured between the region to be the source potential and the region to be the drain potential, and the breakdown voltage can be ensured with a small element size. Note that as illustrated in FIG. 7, the separation region 12 may be provided at least in a region close to the drain region 6.

### Fourth Embodiment

FIG. 10 is a top view of a semiconductor device according to a fourth embodiment.

The fourth embodiment is a modification of the third and second embodiments. The semiconductor device 1 of the fourth embodiment is different from the third and second embodiments in that the separation region 12 is also provided between the body region 3 and the first extension portion 16. Further, the separation region 12 is also provided entirely between the body region 3 and the second extension portion 17. Thus, it is possible to reliably perform insulation. Those other than these are the same as in the third and second embodiments. A cross-sectional view taken along line A-A in FIG. 10 is the same as that of FIG. 8, a cross-sectional view taken along line B-B in FIG. 10 is the same as that of FIG. 9, and a cross-sectional view taken along line C-C in FIG. 10 is the same as that of FIG. 6.

Although the embodiments of the present invention have been described above, the present invention is not limited to the configurations described in the embodiments, and various changes can be made within the scope of the technical idea of the present invention. Further, some or all of the configurations described in the respective embodiments may be combined and applied.

### REFERENCE SIGNS LIST

1: semiconductor device
2: drift region
3: body region
4: source region
5: contact region
6: drain region
7: gate electrode
8: gate insulating film
9: channel region
10: insulating film
11: trench
12: separation region
13: element isolation region
14: embedded insulating film
15: support substrate
16: first extension portion
17: second extension portion

1. A semiconductor device comprising:
a drift region of a first conductivity type;
a body region of a second conductivity type;
a channel region formed in the body region;
a source region of the first conductivity type;
a drain region of the first conductivity type provided on the same main surface side as the source region;
a gate electrode; and
a gate insulating film provided between the gate electrode and the channel region,
wherein a separation region in which an insulating film is provided inside a trench is provided between the drain region and the body region, and
wherein the drift region has a first extension portion which has a longitudinal direction in a first direction by being sandwiched by the body region when viewed in a plan view, and which constitutes a part of a current path between the channel region and the drain region.

2. The semiconductor device according to claim 1,
wherein the drain region is provided on an extension line of the first extension portion.

3. The semiconductor device according to claim 1,
wherein the separation region is also provided between the body region and the first extension portion.

4. The semiconductor device according to claim 1,
wherein the drift region has a second extension portion having a longitudinal direction in a second direction different from the first direction, and constituting a part of a current path between the channel region and the drain region when viewed in a plan view, and
wherein the drain region is provided on an extension line of the second extension portion.

5. The semiconductor device according to claim 4,
wherein the separation region is also provided between the body region and the second extension portion.

6. The semiconductor device according to claim 1, including an element isolation region which surrounds a switching element formed by the drift region, the body region, the channel region, the source region, the drain region, the gate electrode, and the gate insulating film, and in which the insulating film is provided inside the trench.

7. The semiconductor device according to claim 6,
wherein the element isolation region and the separation region are connected to each other.
